(19) United States
(12) Patent Application Publication
(10) Pub. No.: US 2025/0226132 A1
(43) Pub. Date: Jul. 10, 2025

(54) CABLE AND DAMAGE DETECTION DEVICE

(71) Applicant: Proterial, Ltd., Tokyo (JP)

(72) Inventors: Hirotaka ESHIMA, Tokyo (JP); Yoshikazu HAYAKAWA, Ibaraki (JP); Tomoyuki MURAYAMA, Tokyo (JP); Takahiro FUTATSUMORI, Mito-shi (JP)

(73) Assignee: Proterial, Ltd., Tokyo (JP)

(21) Appl. No.: 18/978,468

(22) Filed: Dec. 12, 2024

(30) Foreign Application Priority Data
Jan. 10, 2024 (JP) 2024-002104

(51) Int. Cl. H01B 7/32; G01R 31/08; H01B 7/02; H01B 7/18

(52) U.S. Cl. CPC H01B 7/32; G01R 31/083; H01B 7/0241; H01B 7/187

(57) ABSTRACT

A cable includes a wire bundle composed of a plurality of wires bundled together; a binder tape spirally wound around an outer circumference of the wire bundle; a conductive tape having electrical conductivity and spirally wound around an outer circumference of the binder tape; and a sheath covering the binder tape and the conductive tape. The conductive tape is spirally wound around the outer circumference of the binder tape in such a manner that one end and an other end in a width direction do not overlap, and a spiral winding direction of the conductive tape and a spiral winding direction of the binder tape are opposite. A damage detection device for detecting damage to the cable is configured such that an electric current is applied to the conductive tape and the linear conductor and a damage detection signal indicating that damage has occurred to the cable is output when the electric current is inactive.

### CROSS-REFERENCE TO RELATED APPLICATIONS

The present patent application claims the priority of Japanese patent application No. 2024-002104 filed on Jan. 10, 2024, the entire contents of which are incorporated herein by reference.

### TECHNICAL FIELD

The present invention relates to a cable and a damage detection device for detecting damage to the cable.

### BACKGROUND OF THE INVENTION

Conventionally, a cable and a detection device capable of electrically detecting the occurrence of damage to a cable with multiple wires is known (see, for example, Patent Literature 1).

Patent Literature 1 describes a cable having an outer detection layer composed of a conductive tape with electrical conductivity around the outer circumference of a tape layer composed of a tape body wrapped around the outer circumference of a wire group that bundles a plurality of wires so that damage caused by external damage can be detected when a sudden shock is applied from outside. The conductive tape is wound spirally around the wire group along the axial direction of the wire group. The tape body forming the tape layer is made of an insulating material such as paper or resin. When a disconnection (breakage) occurs in the conductive tape, the characteristic impedance of the conductive tape changes, and the detection device detects this change in characteristic impedance.

In addition, Patent Literature 1 states that this cable can be suitably used in applications such as automobile brake systems, where the impact of wire breakage is significant and the significance of detecting wire breakage before it happens is great.
Citation List Patent Literature 1: JP7151754B

### SUMMARY OF THE INVENTION

For example, cables used for supplying power and control to an electric parking brake device that locks wheel rotation when the vehicle is stopped or an electric brake device that brakes wheel rotation while the vehicle is running are wired in the air in a tire house for a part of their longitudinal direction. In this case, if the cable has a large bending tendency, it may be prone to wear and external damage caused by the cable contacting components of the suspension system and other parts. The cable bending tendency is caused, for example, by twisting multiple wires together, and refers to a property whereby the cable naturally bends in a certain direction even when no external force is exerted on the cable as a single cable. For example, when a conductive tape or an insulating tape body is wrapped around the outer circumference of a wire group, as in the cable described in Patent Literature 1, the wrapping of this conductive tape or tape body may also cause the cable to bend in a certain direction (bending tendency).

It is, therefore, an object of the present invention to provide a cable that has a conductive tape for detecting damage to the cable but can suppress bending tendency, and a damage detection device for detecting damage to the cable.

To solve the problems described above, one aspect of the invention provides a cable, comprising a wire bundle comprising a plurality of wires bundled together; a binder tape spirally wound around an outer circumference of the wire bundle; a conductive tape having electrical conductivity and spirally wound around an outer circumference of the binder tape; and a sheath covering the binder tape and the conductive tape, wherein the conductive tape is spirally wound around the outer circumference of the binder tape in such a manner that one end and an other end in a width direction do not overlap, and wherein a spiral winding direction of the conductive tape and a spiral winding direction of the binder tape are opposite.

To solve the problems described above, another aspect of the invention provides a damage detection device for detecting damage to the cable, wherein an electric current is applied to the conductive tape and the linear conductor and a damage detection signal indicating that damage has occurred to the cable is output when the electric current is inactive.

### Effects of the Invention

According to the invention, it is possible to provide a cable that has a conductive tape for detecting damage to the cable but can suppress bending tendency, and a damage detection device for detecting damage to the cable.

### BRIEF DESCRIPTION OF DRAWINGS

FIG. 1 is a cross-sectional view of a cable in the first embodiment of the invention.

FIG. 2 is an explanatory diagram showing a configuration of a wire bundle, a binder tape, a conductive tape, and a liner conductor.

FIG. 3 is a perspective view showing a binder member and a conductive tape as single units.

FIG. 4 is a cross-sectional view showing the binder member and the conductive tape in a spiral wound state.

FIG. 5A is a circuit diagram showing an example configuration of a damage detection device that detects cable damage.

FIG. 5B is a cross-sectional view showing an example configuration of a linear conductor.

FIG. 6 is a cross-sectional view of a cable in a comparative example.

FIG. 7A is a perspective view showing the conductive tape in a modified example of the first embodiment as a single unit.

FIG. 7B is a cross-sectional view of the conductive tape in the modified example.

FIG. 8A is a cross-sectional view of the cable in the second embodiment of the invention.

FIG. 8B is a cross-sectional view of a vulnerable wire in the cable in the second embodiment.

FIG. 9 is a circuit diagram showing an example configuration of a damage detection device in the second embodiment.

FIG. 10 is a cross-sectional view of a cable in the third embodiment of the invention.

FIG. 11 is an explanatory diagram showing a configuration of a wire bundle, a binder tape, a conductive tape, and a liner conductor in the third embodiment of the invention when viewed from a radial direction of the cable.

### DETAILED DESCRIPTION OF THE INVENTION

### Embodiments

### First Embodiment

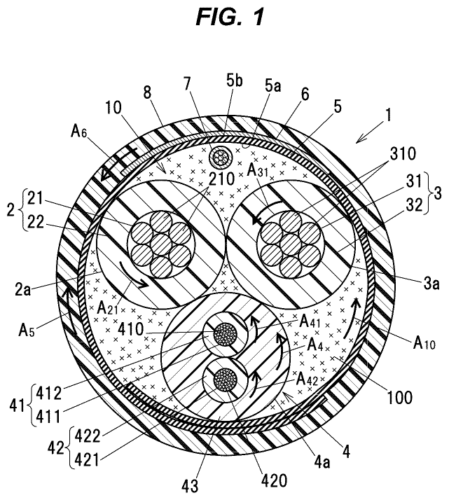

FIG. 1 is a cross-sectional view of a cable 1 in the first embodiment of the invention. The cable 1 comprises a wire bundle 10 consisting of a plurality of wires 2 to 4 bundled together, a binder tape 5 spirally wound around an outer circumference of the wire bundle 10, a conductive tape 6 having electrical conductivity and spirally wound around an outer circumference of the binder tape 5, a linear conductor 7 and fillers 100 covered by the binder tape 5 together with the wire bundle 10, and a sheath 8 covering the binder tape 5 and the conductive tape 6.

In the present embodiment, of the plurality of wires 2 to 4, the first and second wires 2 and 3 are power lines for supplying operating power to a target device. The third wire 4 is a multi-core wire consisting of a pair of signal wires 41 and 42 covered by an inner sheath 43. One ends of the first to third wires 2 to 4 of the cable 1 are connected to unsprung members of a vehicle, and the other ends of the first to third wires 2 to 4 is connected to a control device located on a vehicle body side, which is a sprung member. The target device as the unsprung member that is powered by the first and second wires 2 and 3 is, for example, an electric parking brake device that locks the wheels when the vehicle stops. A pair of signal wires 41 and 42 of the third wire 4 are connected to a wheel speed sensor that detects the rotation speed of the wheel, for example, and transmits output signals of the wheel speed sensor. The cable 1 is repeatedly bent in part of its longitudinal direction as the suspension spring expands and contracts during vehicle travel.

The first wire 2 is an insulated electric wire in which a conductor 21 is covered with an insulator 22. The second wire 3 is an insulated electric wire in which a conductor 31 is covered with an insulator 32. The conductors 21 and 31 are stranded wires consisting of a plurality of strands 210 and 310 made of a good conductive metal such as copper twisted together, respectively. The pair of signal wires 41, 42 of the third wire 4 are insulated electric wires in which conductors 411, 421 are covered with insulators 412, 422, respectively. The conductors 411, 421 are stranded wires consisting of a plurality of strands 410, 420 made of a good conductive metal such as copper twisted together, respectively. The insulators 22, 32 of the first and second wires 2, 3, and the insulators 412, 422 of the pair of signal wires 41, 42 of the third wire 4 are made of fluororesin, for example.

The signal wires 41, 42 of the third wire 4 each have a smaller outer diameter than the first wire 2 and the second wire 3. The respective outer diameters of the signal wires 41, 42 are equal to or less than half the outer diameters of the first wire 2 and the second wire 3. In the present embodiment, although the wire bundle 10 is configured to include one multi-core wire (the third wire 4), a plurality of wires constituting the wire bundle may include a plurality of multi-core wires. The plurality of wires comprising the wire bundle may not include a multi-core wire.

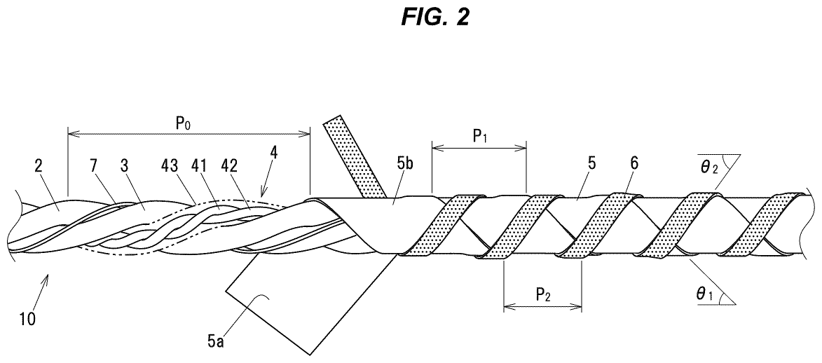

FIG. 2 is a configuration view of the wire bundle 10, the binder tape 5, the conductive tape 6, and the linear conductor 7, viewed from the radial direction of the cable 1, with the fillers 100 and the sheath 8 omitted from the drawing. In FIG. 2, the conductive tape 6 is shown in gray, the contour of the inner sheath 43 of the third wire 4 is shown as a virtual line (double-dotted line) in part of the longitudinal direction of the wire bundle 10, and a pair of signal wires 41, 42 are shown as solid lines.

As shown in FIG. 2, the first to third wires 2 to 4 are twisted together, and the pair of signal wires 41, 42 of the third wire 4 are further twisted together inside the inner sheath 43 to form a twisted pair wire. In FIG. 1, the twisting direction of the first to third wires 2 to 4 is indicated by arrow A₁₀, and the twisting direction of the pair of signal wires 41, 42 in the multi-core wire 4 is indicated by arrow A₄. As shown in FIGS. 1 and 2, the twisting direction of the first to third wires 2 to 4 and the twisting direction of the pair of signal wires 41, 42 in the longitudinal direction of the cable 1 are the same in the present embodiment.

In FIG. 1, the twisting direction of the plurality of strands 210 in the conductor 21 of the first wire 2, the twisting direction of the plurality of strands 310 in the conductor 31 of the second wire 3, and the twisting direction of the plurality of strands 410, 420 of the pair of signal wires 41, 42 in the multi-core wire 4 are indicated by arrows A₂₁, A₃₁, A₄₁, A₄₂, respectively. The twisting direction of these strands 210, 310, 410, 420 is the same as the twisting direction of the first to third wires 2 to 4 and the twisting direction of the pair of signal wires 41, 42. This makes it difficult for the twists of the first to third wires 2 to 4 to unravel.

The filler 100 is made of a fibrous material such as aramid fiber or Kevlar (registered trademark), for example, and is disposed between the first to third wires 2 to 4 and the binder tape 5. The fillers 100 make the shape of the binder tape 5 in a cross-section perpendicular to the longitudinal direction of the cable 1 close to a circle. In other words, the fillers 100 make the shape of the binder tape 5 in the cross-section perpendicular to the longitudinal direction of the wire bundle 10 circular. This allows the cable 1 to flexibly bend in any direction.

The outer diameter of the first wire 2 is the same as the outer diameter of the second wire 3. The outer diameter of the third wire 4 is substantially the same as the outer diameters of the first wire 2 and the second wire 3. Specifically, the outer diameter of the third wire 4 is 95% or more and 105% or less of the outer diameters of the first wire 2 and the second wire 3. This dimensional relationship contributes to circularizing the shape of the binder tape 5 in a cross-section perpendicular to the longitudinal direction of the wire bundle 10.

In the example shown in FIG. 1, a portion of outer circumferential surfaces 2a, 3a, 4a of the respective first to third wires 2 to 4 are in contact with each other and a portion of the outer circumferential surfaces 2a, 3a, 4a of the respective first to third wires 2 to 4 are in contact with the binder tape 5, but the outer circumferential surfaces 2a, 3a, 4a of the respective first to third wires 2 to 4 may not be in contact with each other, and the outer circumferential surfaces 2a, 3a, 4a of the respective first to third wires 2 to 4 may not be in contact with the binder tape 5.

In FIG. 2, an inclination angle of the binder tape 5 with respect to the longitudinal direction of the cable 1 is shown by θ₁ and that of the conductive tape 6 with respect to the longitudinal direction of the cable 1 is shown by θ₂. The spiral winding pitch of the binder tape 5 in the longitudinal direction of the cable 1 is shown by P₁, and the spiral winding pitch of the conductive tape 6 in the longitudinal direction of the cable 1 is shown by P₂. Further, a twisting pitch of the first to third wires 2 to 4 is shown by P_{O}. The spiral winding pitch here refers to the length that the binder tape 5 and the conductive tape 6 advance in the longitudinal direction of the wire bundle 10 during one lap around the outer circumference of the wire bundle 10 when the binder tape 5 and the conductive tape 6 are wound around the outer circumference of the wire bundle 10. The twisting pitch here refers to the length that the first to third wires 2 to 4 advance in the longitudinal direction of the wire bundle 10 during one lap around the center of the wire bundle 10 when the first to third wires 2 to 4 are twisted.

As shown in FIG. 2, the inclination angle θ₂ of the conductive tape 6 to the longitudinal direction of the cable 1 is larger than the inclination angle θ₁ of the binder tape 5, and the spiral winding pitch P₂ of the conductive tape 6 in the longitudinal direction of the cable 1 is narrower than the spiral winding pitch P₁ of the binder tape 5. The spiral winding pitch P₂ of the conductive tape 6 and the spiral winding pitch P₁ of the binder tape 5 narrower than the twisting pitch P_{O} of the first to third wires 2 to 4.

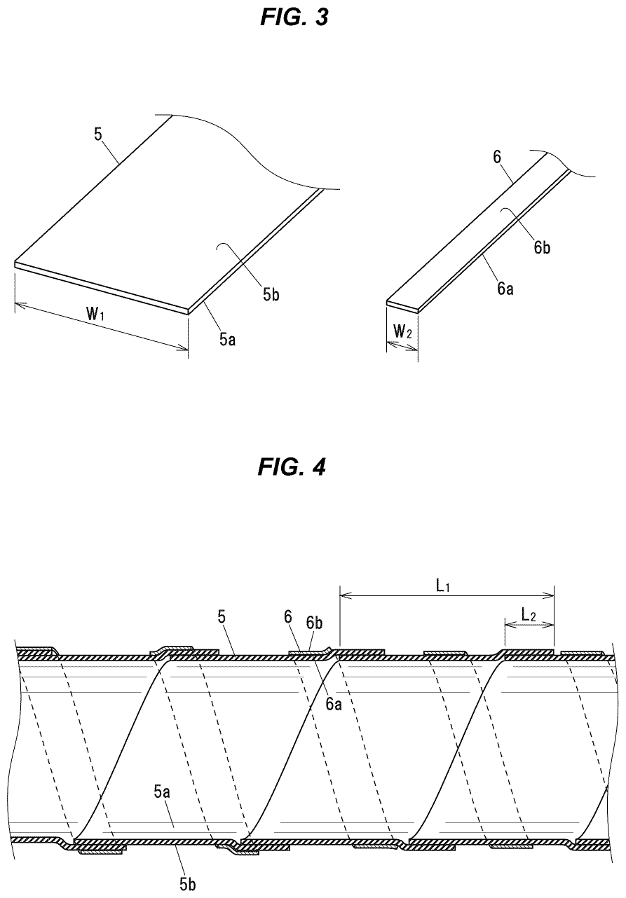

FIG. 3 is a perspective view showing the binder tape 5 and the conductive tape 6 as single units. FIG. 4 is a cross-sectional view showing the binder tape 5 in its spiral wound state and the conductive tape 6 wound around the outer circumference of the binder tape 5.

The conductive tape 6 is a strip of electrically conductive material. In this embodiment, the conductive tape 6 is a strip of metal foil made of a good conductive metal such as copper, silver, or aluminum. The conductive tape 6 is wound around the outer circumference of the binder tape 5 with one side 6a contacting the other side 5b of the binder tape 5. The one side 6a of the conductive tape 6 is given adhesiveness by an adhesive and adheres to the other side 5b of the binder tape 5. The other side 6b of the conductive tape 6 contacts the sheath 8. If the frictional force with the binder tape 5 or the sheath 8 sufficiently suppresses the shifting (i.e., misalignment) of the conductive tape 6 in the longitudinal direction of the cable 1 and prevents one end and the other end in the width direction of different turns of the conductive tape 6 from contacting each other, the adhesiveness of the one side 6a of the conductive tape 6 may not be necessary to prevent the contact of one end with the other end in the width direction of the different turns of the conductive tape 6.

In FIG. 3, a width of the binder tape 5 is shown by W₁ and a width of the conductive tape 6 is shown by W₂. The width W₁ of the binder tape 5 is wider than the width W₂ of the conductive tape 6, and the desirable range of the width W₂ of the conductive tape 6 relative to the width W₁ of the binder tape 5 is, for example, 10% or more and 30% or less. In addition, the thickness of the conductive tape 6 is thinner than the thickness of the binder tape 5. However, this is not limited to this, and the conductive tape 6 may be thicker than the binder tape 5. The narrower and thinner the conductive tape 6 is, the more sensitive it is when the cable 1 is damaged, but on the other hand, it is more prone to wear and kink due to friction with the sheath 8 when the cable 1 is bent, for example. Therefore, the width and thickness of conductive tape 6 is desirably adjusted appropriately according to the application and use environment of the cable 1.

The binder tape 5 is a strip of, for example, non-woven fabric, paper, or resin such as polyester, and wrapped around the first to third wires 2 to 4 to press them toward the center of the cable 1. The binder tape 5 is overlapped and wound around the outer circumference of the wire bundle 10 in such a manner that the width-directional ends overlap each other in the radial direction of the cable 1. More specifically, the one side 5a of the end of the binder tape 5 on one side in the width direction and the other side 5b of the end of the binder tape 5 on the other side in the width direction overlap and contact each other in the thickness direction of the binder tape 5. In the longitudinal direction of the cable 1 (right and left direction in FIG. 4), the ratio of the overlapping length L₂ of the binder tape 5 to the length L₁ of the binder tape 5 for one turn is, for example, 10% or more and 40% or less.

The conductive tape 6 is coarsely wound around the outer circumference of the binder tape 5 in such a manner that one end and the other end in the width direction do not overlap. A gap is formed between one end and the other end in the width direction of the conductive tape 6 to expose the other side 5b of the binder tape 5. The one side 5a of the binder tape 5 in this gap is in contact with the sheath 8.

The sheath 8 is made of urethane resin, such as thermoplastic polyurethane, and is extruded around the outer circumference of the binder tape 5. The binder tape 5 covers the entire circumference of the wire bundle 10 in cross-sectional view. This prevents the liquid thermoplastic resin forming the sheath 8 from entering between the first to third wires 2 to 4 during the molding of the sheath 8.

In FIG. 1, the spiral winding direction of the binder tape 5 is indicated by arrow As and the spiral winding direction of the conductive tape 6 is indicated by arrow A₆. As shown in FIG. 1, when the wire bundle 10, the binder tape 5, and the conductive tape 6 are viewed in the longitudinal direction of the cable 1 from a cross-section perpendicular to the longitudinal direction of the cable 1, the twisting direction of the first to third wires 2 to 4 in the wire bundle 10 and the spiral winding direction of the binder tape 5 are opposite. The spiral winding direction of the conductive tape 6 is the same as the twisting direction of the first to third wires 2 to 4 in the wire bundle 10 and opposite to the spiral winding direction of the binder tape 5.

The cable 1 constructed as described above may be subjected to the external damage due to impact by, for example, chipping during vehicle driving, or the sheath 8 may be severely abraded by friction with the outside. When the cable 1 is damaged by such external damage or wear, the occurrence of damage is detected by the damage detection device described below.

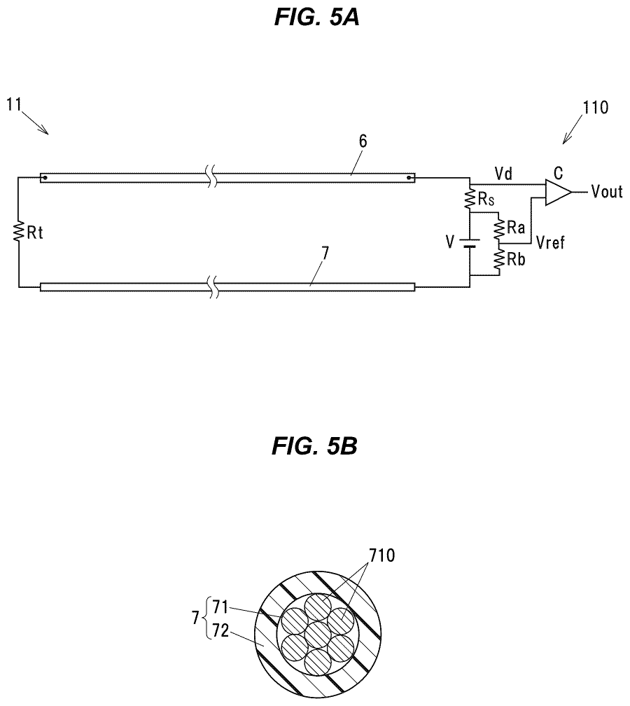

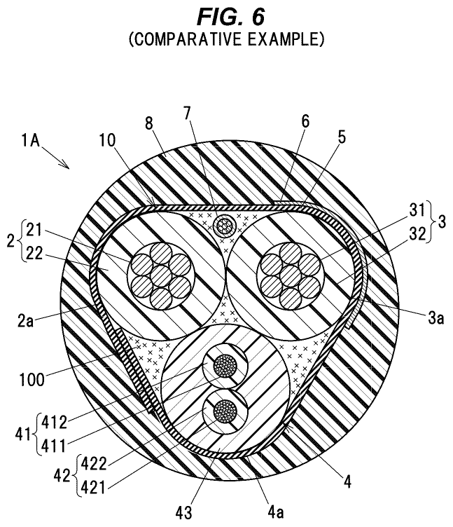

FIG. 5A is a circuit diagram showing an example configuration of the damage detection device 11 that detects damage to the cable 1. FIG. 5B is a cross-sectional view showing an example configuration of the linear conductor 7. The damage detection device 11 includes the conductive tape 6 and the linear conductor 7 as components and is configured to include a damage detection circuit 110 that electrically detects the occurrence of damage in the cable 1.

The linear conductor 7 is an insulated electric wire having a conductor 71 and an insulator 72 covering the conductor 71, as shown in FIG. 5B. In the example shown in FIG. 5B, the conductor 71 is a stranded wire consisting of a plurality of strands 710 twisted together, but the conductor 71 may be a single wire. The insulator 72 may be omitted and the linear conductor 7 may be an uncoated wire (bare wire).

The linear conductor 7 is placed inside the binder tape 5 together with the first to third wires 2 to 4, and the conductor 71 of the linear conductor 7 is electrically connected to the conductive tape 6 at one terminal in the longitudinal direction of the cable 1. In the present embodiment, this terminal is a vehicle unsprung side end. The example shown in FIG. 5A shows a case in which the conductive tape 6 and the linear conductor 7 are connected by a termination resistor Rt. However, this is not limited to this case, and the conductor 71 of the linear conductor 7 may be directly connected to the conductive tape 6 and short-circuit them.

The linear conductor 7 has a lower bending endurance than the first to third wires 2 to 4, and when the cable 1 is repeatedly bent, it breaks before any of the first to third wires 2 to 4 break. The conductor cross-sectional area of the conductor 71 of the linear conductor 7 is smaller than the conductor cross-sectional area of the conductor 21 of the first wire 2, the conductor 31 of the second wire 3, and the conductors 411 and 421 of signal wires 41 and 42 of the third wire 4, respectively.

In the present embodiment, as shown in FIG. 1, the linear conductor 7 is placed between the first and second wires 2 and 3 and the binder tape 5. However, the position of the linear conductor 7 is not limited to this, for example, the linear conductor 7 may be placed in the center of the cable 1 surrounded by the first to third wires 2 to 4. The linear conductor 7 may be spaced apart from the wire bundle 10 or may be in contact with the wire bundle 10 as shown in FIG. 1.

The damage detection circuit 110 is provided on the opposite side (sprung side) from the side where the conductive tape 6 and the conductor 71 of the linear conductor 7 are electrically connected in the longitudinal direction of the cable 1. The damage detection circuit 110 applies an electric current to the conductive tape 6 and the wire conductor 7, and outputs a damage detection signal to report the occurrence of damage to the cable 1 when this current is inactive. When this damage detection signal is output, the occurrence of damage to the cable 1 is reported to the driver, for example, by lighting a lamp on the instrument panel of the vehicle.

In the circuit example configuration of the damage detection circuit 110 shown in FIG. 5A, a shunt resistor Rs, the conductive tape 6, the termination resistor Rt, and the linear conductor 7 are connected in series between the + (positive) and − (negative) sides of a DC power supply V. The damage detection circuit 110 is also configured to include first and second reference resistors Ra, Rb connected in series between the + and − sides of the DC power supply V, and a comparator C, and a reference voltage Vref, which is the voltage obtained by resistively dividing the voltage of the DC power supply V by the first and second reference resistors Ra and Rb, and the detection voltage Vd, which is the voltage on the conductive tape 6 side of the shunt resistor Rs, are input to the comparator C.

If there is no breakage in any of the conductive tape 6 and the conductor 71 of the linear conductor 7, and a predetermined current is flowing in the series circuit consisting of the shunt resistor Rs, the conductive tape 6, the termination resistor Rt, and the linear conductor 7, a voltage drop corresponding to the magnitude of that current occurs in the shunt resistor Rs, and the detection voltage Vd becomes lower than the voltage of the DC power supply V. On the other hand, if any of the conductive tape 6 and the conductor 71 of the linear conductor 7 are disconnected, no current flows in this series circuit, and the detection voltage Vd becomes equal to the voltage of the DC power supply V.

The reference voltage Vref is adjusted to be a value between the detection voltage Vd when no breakage occurs in the conductive tape 6 and the conductor 71 of the linear conductor 7 and the detection voltage Vd. When a breakage occurs in any of the conductive tape 6 and the conductor 71 of the linear conductor 7, the output voltage Vout of the comparator C changes. The output voltage Vout of the comparator C is output from the damage detection circuit 110 as a damage detection signal indicating that damage has occurred in the cable 1.

### COMPARATIVE EXAMPLE

FIG. 6 is a cross-sectional view of a cable 1A in a comparative example. In FIG. 6, components that are common to the components of the cable 1 in the first embodiment are marked with the same symbols as those in FIG. 1, etc., and redundant explanations are omitted.

In the cable 1A, the binder tape 5 has a triangular shape with rounded corners in the cross-section of the cable 1A. That is, at each corner of this triangular shape, the binder tape 5 is curved along the outer circumferential surfaces 2a, 3a, and 4a of the first wire 2, the second wire 3, and the third wire 4 with the curvature of the outer circumferential surface 2a, 3a, and 4a of these wires.

In this cable 1A, compared to the cable 1 in the first embodiment, the conductive tape 6 is subjected to stress due to bending at a large curvature, and this stress causes the conductive tape 6 to break easily, and false detection of damage is likely to occur. Meanwhile, in the cable 1 in the first embodiment, the shape of the binder tape 5 in the cross-section perpendicular to the longitudinal direction of the wire bundle 10 is circular, and the curvature of the binder tape 5 is smaller than that of the outer circumferential surfaces 2a, 3a, 4a of the first to third wires 2 to 4, so stress due to bending in the conductive tape 6 to be wound around the outer circumference of the binder tape 5 is less likely to occur and this prevents the occurrence of false detection.

### Effects of the First Embodiment

According to the first embodiment described above, since the spiral winding direction of the conductive tape 6 and the spiral winding direction of the binder tape 5 are opposite, the bending tendency of the cable 1 caused by the spiral winding of the binder tape 5 and the bending tendency of the cable 1 caused by the spiral winding of the conductive tape 6 are canceled out, so that the bending tendency of the cable 1 is suppressed as a whole.

According to the first embodiment described above, since the spiral winding direction of the binder tape 5 and the twisting direction of the first to third wires 2 to 4 are opposite, the bending tendency of the cable 1 caused by the twisting of the first to third wires 2 to 4 and the bending tendency of the cable 1 caused by the spiral winding of the binder tape 5 are canceled out. In addition, the excessive twisting of the first to third wires 2 to 4 due to corotation (co-winding) with the binder tape 5 when wrapping the binder tape 5 is suppressed.

According to the first embodiment, the spiral winding pitch of the conductive tape 6 is narrower than that of the binder tape 5, so that the number of turns of the conductive tape 6 per unit length in the longitudinal direction of the cable 1 increases compared to the case where the conductive tape 6 is spirally wound with the spiral winding pitch P₁ of the binder tape 5 shown in FIG. 2, for example. The number of turns of the conductive tape 6 per unit length in the longitudinal direction of the cable 1 is increased, making it possible to detect the occurrence of damage even if the size of the damage is small when the external damage occurs to the sheath 8.

In the first embodiment, the width of the binder tape 5 is wider than the width of the conductive tape 6, and the inclination angle of the binder tape 5 with respect to the longitudinal direction of the cable 1 is smaller than that of the conductive tape 6. Therefore, compared to, for example, the case of spirally winding the binder tape 5 with the inclination angle θ₂ of the conductive tape 6 shown in FIG. 2, the number of turns of the binder tape 5 per unit length of the cable I can be reduced, and the man-hours required for manufacturing the cable I can be reduced. In other words, in the first embodiment, by making the spiral winding pitch of the conductive tape 6 narrower than the spiral winding pitch of the binder tape 5 and the width of the binder tape 5 wider than the width of the conductive tape 6, the sensitivity of damage to the cable 1 is improved and manufacturing costs are reduced. In the case of layered winding of a strip such as the binder tape 5, there is a correlation between the width of the strip and the inclination angle, with a wider width resulting in a smaller inclination angle and a narrower width resulting in a larger inclination angle.

According to the first embodiment, even when the linear conductor 7 has a lower bending endurance than the first to third wires 2 to 4 and the linear conductor 7 breaks, the occurrence of the breakage is detected by the damage detection circuit 110. Therefore, in addition to sudden external damage due to the impact of chipping or the wear of the sheath 8, the breakage of the linear conductor 7 can detect the signs of breakage of the first to third wires 2 to 4 caused by metal fatigue due to repeated bending.

### Modified Example of the First Embodiment

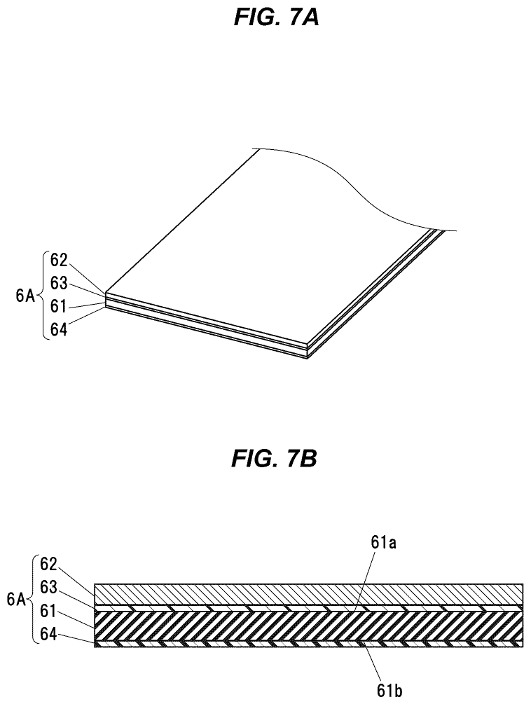

FIG. 7A is a perspective view of a conductive tape 6A as a single unit in a modified example of the first embodiment. FIG. 7B is a cross-sectional view of the conductive tape 6A in a cross-section perpendicular to a longitudinal direction of the conductive tape 6A. In FIGS. 7A and 7B, the thickness of the conductive tape 6A is exaggerated for clarity of explanation.

The conductive tape 6A includes a base material 61 made of a strip-shaped insulator and a conductive layer 62 provided on one side 61a of the base material 61. The conductive layer 62 is reinforced by the base material 61 in such a manner that it does not easily break even when repeatedly bent. In this example, the strip-shaped conductive layer 62 is bonded to the one side 61a of the base material 61 via a bonding layer 63. An adhesive layer 64 is provided on the other side 61b of the base material 61. The conductive layer 62 may be formed on the one side 61a of the base material 61 by vapor deposition.

The conductive tape 6A replaces the conductive tape 6 in the first embodiment, and is spirally wound around the outer circumference of the binder tape 5 in the same manner as the conductive tape 6. When winding the conductive tape 6A, it may be wound in such a manner that the conductive layer 62 is outside (sheath 8 side) of the base material 61 or the conductive layer 62 is inside (binder tape 5 side) of the base material 61. If the conductive layer 62 is outside of the base material 61, damage to the cable 1 can be detected with high sensitivity. If the conductive layer 62 is inside with respect to the base material 61, the conductive layer 62 can be prevented from being worn by friction with the sheath 8. To prevent the shifting (misalignment) of the conductive tape 6A, an adhesive layer can be provided on the side of the binder tape 5 in the conductive tape 6A.

When using the conductive tape 6A, a shunt resistor Rs, a conductive layer 62 of the conductive tape 6A, a termination resistor Rt, and a linear conductor 7 are connected in series between the + (positive) and − (negative) sides of the DC power supply V of the damage detection circuit 110 to detect the breakage by the damage detection device 11 when the conductive layer 62 is broken.

Even when the conductive tape 6A in the modified example is used, the same effects as in the first embodiment can be obtained. The conductive layer 62 may be provided only on the one side 61a of the base material 61 as shown in FIGS. 7A and 7B, but the conductive layer 62 may be provided on the one side 61a and the other side 61b of the base material 61 respectively. In this case, by electrically connecting the conductive layer 62 on the one side 61a of the base material 61 with the conductive layer 62 on the other side 61b at the longitudinal end of the conductive tape 6A, making one of the conductive layers 62 on both sides the outward path of the current supplied from the damage detection circuit 110 and the other the return path of this current, the linear conductor 7 can be omitted.

### Second Embodiment

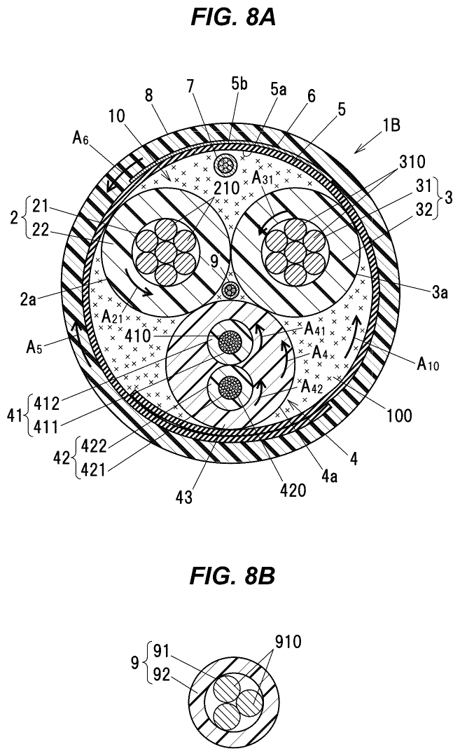

FIG. 8A is a cross-sectional view of a cable 1B in the second embodiment of the invention. The cable 1B in the second embodiment corresponds to the cable 1 in the first embodiment to which a vulnerable (weak, fragile, brittle) wire 9 is added, which has a lower bending endurance than the first to third wires 2 to 4 and is more prone to breakage. The vulnerable wire 9 is located in the center of the cable 1B surrounded by the first to third wires 2 to 4 and extends in the longitudinal direction of the cable 1B.

FIG. 8B is a cross-sectional view of the vulnerable wire 9. The vulnerable wire 9 is an insulated electric wire having a conductor 91 and an insulator 92 covering the conductor 91. The conductor 91 is a stranded wire consisting of a plurality of strands 910 twisted together, but it is not limited to this, and the conductor 91 may be a single wire. The insulator 92 may be omitted and the vulnerable wire 9 may be an uncoated wire (bare wire).

The vulnerable wire 9 is used to detect the signs (specifically, predictive signs) of breakage of any of the first or third wires 2 to 4 before it occurs due to repeated bending of the cable 1B. In other words, in the present embodiment, the occurrence of damage such as sudden external damage due to chipping, etc. or wear of the sheath 8 is detected by the breakage of the conductive tape 6, and the signs of breakage due to metal fatigue of the conductors 21, 31, 411, 421 of the first to third wires 2 to 4 are detected by the breakage of the vulnerable wire 9. The conductor thickness of the conductive tape 6 is thinner than the conductor diameter of the conductor 91 of the vulnerable wire 9. This allows sensitive detection of wear and external damage to the sheath 8.

In the cable 1B, instead of the conductive tape 6, the conductive tape 6A shown in FIGS. 7A and 7B may be used. In this case, the thickness of the conductive layer 62 of the conductive tape 6A is thinner than the conductor diameter of the conductor 91 of the vulnerable wire 9.

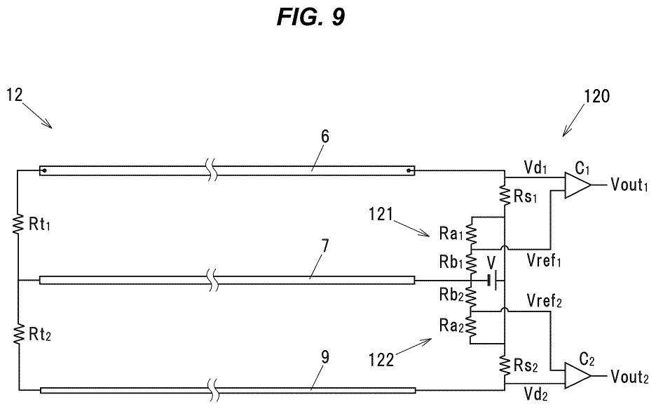

FIG. 9 is a circuit diagram showing an example configuration of a damage detection device 12 in the second embodiment. The damage detection device 12 includes the conductive tape 6, the vulnerable wire 9, and the linear conductor 7 of the cable 1B as components, and comprises a damage detection circuit 120. The damage detection circuit 120 has a first circuit section 121 for detecting breakage of the conductive tape 6, and a second circuit section 122 for detecting breakage of the conductor 91 of the vulnerable wire 9.

The first circuit section 121 of the damage detection circuit 120 has reference resistors Ra₁, Rb₁ that generate the reference voltage Vref₁ by resistively dividing the voltage of the DC power supply V, a shunt resistor Rs₁, and a comparator C₁ that compares the detection voltage Vd₁, which is the voltage on the conductive tape 6 side of the shunt resistor Rs₁, with the reference voltage Vref₁ and the output voltage Vout₁ of the comparator C₁ changes when a breakage occurs in the conductive tape 6. The conductive tape 6 and the linear conductor 7 are electrically connected by a first termination resistor Rt₁ at a longitudinal terminal of the cable 1B, which is the end opposite to the damage detection circuit 120.

The second circuit section 122 of the damage detection circuit 120 has reference resistors Ra₂, Rb₂ that generate the reference voltage Vref₂ by resistively dividing the voltage of the DC power supply V, a shunt resistor Rs₂, and a comparator C₂ that compares the detection voltage Vd₂, which is the voltage on the vulnerable wire 9 side of the shunt resistor Rs₂, with the reference voltage Vref₂. The output voltage Vout₂ of the comparator C₂ changes when a breakage occurs in the conductor 91 of the vulnerable wire 9. The conductor 91 of the vulnerable wire 9 and the linear conductor 7 are electrically connected by a second termination resistor Rt₂ at a longitudinal terminal of the cable 1B, which is the end opposite to the damage detection circuit 120.

The output voltage Vout₁ of the comparator C₁ of the first circuit section 121 is output from the damage detection circuit 120 as a damage detection signal indicating that damage has occurred in the cable 1B. The output voltage Vout₂ of the comparator C₂ of the second circuit section 122 is output from the damage detection circuit 120 as a sign detection signal indicating that there are signs of breakage in the first to third wires 2 to 4 of the cable 1B. When the damage detection signal or the sign detection signal is output, the driver is informed, for example, by the lighting of a lamp on the instrument panel of the vehicle.

According to the second embodiment, it is possible to reduce the occurrence of detection omissions and false detections while suppressing the increase in man-hours during manufacturing, and to detect signs of wire breakage due to metal fatigue in the conductors 21, 31, 411, 421 of the first to third wires 2 to 4 by the vulnerable wire 9. In the first embodiment, the linear conductor 7 has a lower bending endurance than the first to third wires 2 to 4, but in the third embodiment, since the vulnerable wires 9 can detect the signs of breakage of the first to third wires 2 to 4, the bending endurance of the linear conductor 7 does not have to be lower than the bending endurance of the first to third wires 2 to 4. The vulnerable wire 9 does not necessarily have to be used for the first and third wires 2 to 4. The vulnerable wire 9 does not necessarily have to be located in the center of the cable 1B, and the vulnerable wire 9 may be placed between the first to third wires 2 to 4 and the binder tape 5. In this case, the vulnerable wire 9 is twisted together with the first to third wires 2 to 4 and the linear conductor 7.

### Third Embodiment

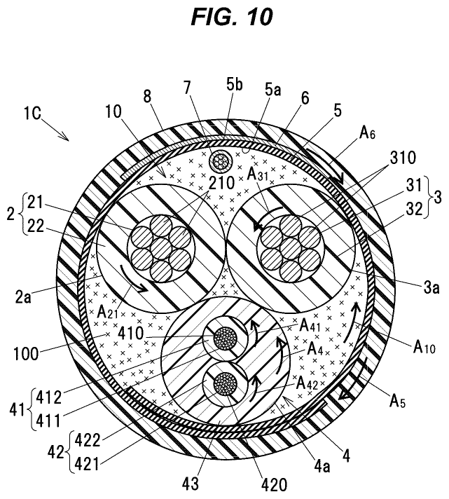

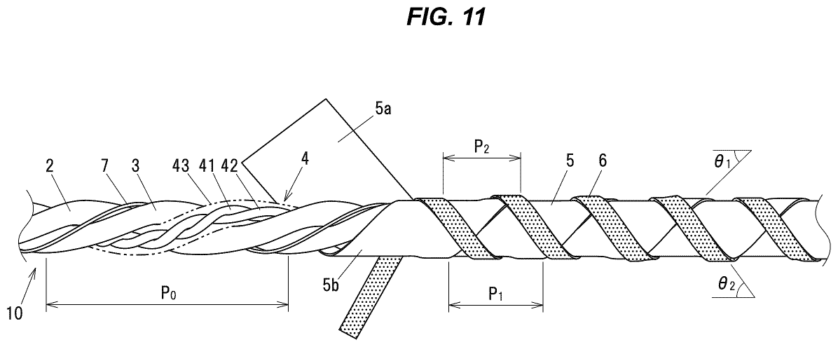

FIG. 10 is a cross-sectional view of a cable 1C in the third embodiment. FIG. 11 is a configuration diagram of the wire bundle 10, the binder tape 5, the conductive tape 6, and the linear conductor 7 as viewed from the radial direction of the cable 1C, in which illustrations of the filler 100 and the sheath 8 are omitted.

In the first embodiment, the case in which the twisting direction of the first to third wires 2 to 4 in the wire bundle 10 and the spiral winding direction of the binder tape 5 are opposite, and the spiral winding direction of the binder tape 5 and the spiral winding direction of the conductive tape 6 are opposite was described. In the third embodiment, the twisting direction of the first to third wires 2 to 4 in the wire bundle 10 and the spiral winding direction of the binder tape 5 are the same, and the spiral winding direction of the binder tape 5 and the spiral winding direction of the conductive tape 6 are opposite. The configuration of the cable 1C other than this is the same as the configuration of the cable 1 in the first embodiment. In other words, in the third embodiment, the inclination angle θ₂ of the conductive tape 6 with respect to the longitudinal direction of the cable 1C is larger than the inclination angle θ₁ of the pressing and winding tape 5, and the spiral winding pitch P₂ of the conductive tape 6 in the longitudinal direction of the cable 1C is narrower than the spiral winding pitch P₁ of the binder tape 5.

In the same way as in the first embodiment, the bending tendency of the cable 1C caused by the spiral winding of the binder tape 5 and the bending tendency of the cable 1C caused by the spiral winding of the conductive tape 6 are canceled out, so that the bending tendency of the cable 1C caused by the spiral winding of the binder tape 5 and the conductive tape 6 is suppressed. If damage occurs to the cable 1C, the occurrence of the damage is detected by the damage detection device 11 described in the first embodiment.

### Summary of Embodiments

Next, the technical concepts that can be grasped from the above embodiments and modified examples will be described with the aid of the code and symbols, etc. in the embodiments and modified examples. However, each code and symbols in the following description does not limit the constituent elements in the scope of claims to the members, etc. specifically shown in the embodiments.

According to the first feature, a cable 1, 1B, 1C includes a wire bundle 10 including a plurality of wires 2 to 4 bundled together, a binder tape 5 spirally wound around an outer circumference of the wire bundle 10, an electrically conductive tape 6, 6A spirally wound around an outer circumference of the binder tape 5, and a sheath 8 covering the binder tape 5 and the conductive tape 6, 6A, wherein the conductive tape 6, 6A is spirally wound around the outer circumference of the binder tape 5 in such a manner that one end and an other end in a width direction do not overlap, wherein a spiral winding direction of the conductive tape 6 and a spiral winding direction of the binder tape 5 are opposite.

According to the second feature, in the cable 1, 1B as described in the first feature, the plurality of wires 2 to 4 are twisted together, wherein the spiral winding direction of the binder tape 5 and a twisting direction of the plurality of wires 2 to 4 are opposite.

According to the third feature, in the cable 1, 1B, 1C as described in the first feature, a spiral winding pitch P₂ of the conductive tape 6, 6A is narrower than a spiral winding pitch P₁ of the binder tape 5.

According to the fourth feature, in the cable 1, 1B, IC as described in the first feature, a width W₁ of the binder tape 5 is wider than a width W₂ of the conductive tape 6, 6A.

According to the fifth feature, in the cable 1, 1B, 1C as described in any one of the first feature to the fourth feature, further includes a linear conductor 7 electrically connected to the conductive tape 6, 6A at one terminal in a cable longitudinal direction, wherein the linear conductor 7 is arranged together with the plurality of wires 2 to 4 inside the binder tape 5.

According to the sixth feature, a damage detection device 11, 12 for detecting damage to the cable 1, 1B, 1C as described in the fifth feature is configured in such a manner that an electric current is applied to the conductive tape 6, 6A and the linear conductor 7 and a damage detection signal indicating that damage has occurred to the cable 1, 1B, 1C is output when the electric current is inactive.

The above description of the embodiments and modified examples of the invention does not limit the invention as claimed. It should also be noted that not all of the combinations of features described in the embodiments and modified examples are essential to the means for solving the problems of the invention. In addition, the invention can be implemented by modifying it as appropriate to the extent that it does not depart from the intent of the invention, for example, the invention can be implemented by modifying it as follows.

In the above embodiments, the case in which the third wire 4, which is a multi-core wire, has a plurality of signal wires 41, 42 as small diameter wires was described. The plurality of small diameter wires constituting the multi-core wire may be used as power supply lines to supply an operating power source to a target device. The target devices include, for example, an active suspension device with variable damping force and an air pressure sensing device that detects the air pressure of tires.

In the above embodiments, the first and second wires 2 and 3 are used as power supply lines to supply operating power to the electric parking brake device, and the signal wires 41 and 42 of the third wire 4 are used to transmit the output signal of the wheel speed sensor. However, the application of the first to third wires 2 to 4 is not limited thereto. For example, the first wire 2 and the second wire 3 may be used as power supply lines for supplying operating power to the electric brake device that brakes the rotation of the wheels while the vehicle is running, and the signal wires 41 and 42 of the third wire 4 may be used to transmit control signals for controlling the electric brake device.

In the above embodiments, the case in which three wires (first to third wires 2 to 4) are bundled together to form the wire bundle 10 was described, but this is not limited to the case in which the number of wires may be two or four or more.

In the above embodiments, the case of detecting a breakage of the conductive tape 6, 6A by constantly applying a DC current to the conductive tape 6 was described, but it is not limited to this case. For example, the breakage of the conductive tape 6, 6A can be detected by intermittently applying an electric current to the conductive tape 6, 6A.

In the above embodiment, the case where cable 1 is installed in a vehicle was described, but this is not limited to this, and the cable I may also be used in industrial machinery such as robots and machine tools.

1. A cable, comprising:
a wire bundle comprising a plurality of wires bundled together;
a binder tape spirally wound around an outer circumference of the wire bundle;
a conductive tape having electrical conductivity and spirally wound around an outer circumference of the binder tape; and
a sheath covering the binder tape and the conductive tape,
wherein the conductive tape is spirally wound around the outer circumference of the binder tape in such a manner that one end and an other end in a width direction do not overlap,
wherein the conductive tape is spirally wound around the outer circumference of the binder tape in such a manner that one end and an other end in a width direction do not overlap, and
wherein a spiral winding direction of the conductive tape and a spiral winding direction of the binder tape are opposite.

2. The cable, according to claim 1, wherein the plurality of wires are twisted together, wherein the spiral winding direction of the binder tape and a twisting direction of the plurality of wires are opposite.

3. The cable, according to claim 1, wherein a spiral winding pitch of the conductive tape is narrower than a spiral winding pitch of the binder tape.

4. The cable, according to claim 1, wherein a width of the binder tape is wider than a width of the conductive tape.

5. The cable, according to claim 1, further comprising:
a linear conductor electrically connected to the conductive tape at one terminal in a cable longitudinal direction,
wherein the linear conductor is arranged together with the plurality of wires inside the binder tape.

6. A damage detection device for detecting damage to the cable according to claim 5, wherein an electric current is applied to the conductive tape and the linear conductor and a damage detection signal indicating that damage has occurred to the cable is output when the electric current is inactive.
